(19) United States
(12) Patent Application Publication
(10) Pub. No.: US 2023/0127700 A1
(43) Pub. Date: Apr. 27, 2023

(54) Break-resistant electric remote control

(71) Applicant: fm marketing gmbh, Neumarkt am Wallersee (AT)

(72) Inventor: Ferdinand Maier, Neumarkt am Wallersee (AT)

(21) Appl. No.: 17/971,401

(22) Filed: Oct. 21, 2022

(30) Foreign Application Priority Data
Oct. 21, 2021 (DE) 10 2021 127 425.7

(51) Int. Cl. H05K 5/02; H05K 5/00; C08L 69/00; C08L 55/02

(52) U.S. Cl. CPC H05K 5/0217; H05K 5/0017; C08L 69/00; C08L 55/02; C08L 2203/20

(57) ABSTRACT

A remote control for operating an electronic device comprising a plastic housing with a plastic plate segment with a control panel which has at least one control element, preferably button elements and/or at least one directional pad for operating an electronic device,

wherein the plastic plate segment is formed from a plastic material which has an Charpy impact strength of more than 6 kJ/m², in particular of 9.0 kJ/m²+/−0.3 kJ/m², wherein the plastic material is an isosorbide-based polymer.

### CROSS-REFERENCE TO RELATED APPLICATION

This application claims priority from the German patent application 10 2021 127 425.7 filed Oct. 21, 2021, the content of which is incorporated herein in the entirety by reference.

### TECHNICAL FIELD

The present invention relates to a break-resistant electric remote control pursuant to the preamble of the valid claim 1

### BACKGROUND

Remote controls are known from everyday life. They can be used to control electronic devices, e.g. television sets, radios, air conditioners or the like. Signals can be transmitted by sending a control signal, using both radio signals according to the Bluetooth low-energy standard and optical signals (e.g. infrared). One or more signal transmitters for both types of signal can also be advantageously integrated in a remote control. This also enables bidirectional communication, among other things.

A disadvantage in everyday use is the breakage of plastic housings with such electric remote controls. To improve this, various plastics have been used so far. For example, PMMA has a wide variation in notched impact strength, and many PMMA compounds are only scratch-resistant to a small degree. PMMA plastics with high notched impact strength also have a low elongation at break as a measure of plastic deformation, e.g. 5%. This means that the material is only slightly deformable. A mechanical impact on the material is therefore not dampened by deformation. Common polycarbonates also have an elongation at break of less than 50%.

Isosorbide-based polymers are used as paints or in the interior trim of automobiles. Mechanical shocks, such as those that occur when remote controls are dropped, do not occur because these components are permanently installed.

Exposure of car components to grease or sweat also does not occur in this area, or only in the case of the steering wheel, which is usually made of other materials such as artificial leather.

However, to ensure tightness and protection of the electronics from moisture and other influences, the plastic housing should ideally respond to excessive mechanical stress by plastic deformation before breakage occurs.

Further preferred, both for signal transmission in the case of optical signal transmission, and for optical appearance, is the light transmittance. PMMA has ideal transparency and brilliance in this respect.

Conventional polycarbonates and many other plastics also have a low stability against fatty acids. Hand creams and other fats on the skin can penetrate the polymers by diffusion and cause clouding or a greasy sheen. This effect cannot be removed by cleaning.

The same applies to salt solutions and other electrolyte solutions such as sweat. Usually, plastics do not come into permanent exposure to sweat and grease. Remote controls are an exception here. It was surprisingly found that even ABS, which is known for high chemical stability, is subject to an increased degree of surface alteration in the case of highly frequent exposure to the hand and the substances on it.

Based on this preliminary consideration, it is the task of the present invention to provide a remote control with a plastic housing which has higher break resistance than conventional polycarbonate or PMMA.

Optimally, this break resistance can be supplemented by further features which are advantageous for the field of application of remote controls.

### SUMMARY

The present invention solves the aforementioned problem by a break-resistant remote control with the features of claim 1.

A break-resistant electric remote control according to the invention can in particular be designed as a remote control for operating an electronic device. It comprises a plastic housing with a plastic plate segment. This plastic plate segment can be flat or may have a single or multiple curvatures. The plastic plate segment has a control panel which has at least one control element for operating the electronic device, in particular for inputting a control command to the electronic device. The control element can preferably be designed as one or more button elements and/or be designed as at least one directional pad. The plastic plate segment is formed, in particular moulded, from a plastic material which has a notched impact strength according to Charpy of more than 6.0 kJ/m², in particular 9.0+/−0.3 kJ/m², in a notched specimen.

According to the invention, the plastic material is formed as an at least partially isosorbide-based polymer. Thus, in addition to the notched impact strength, an increased resistance to perspiration, especially hand perspiration, is also formed.

Advantageous embodiments of the invention are the subject matter of the dependent claims.

In particular and especially advantageous, the plastic plate segment has a higher resistance to perspiration than ABS (acrylonitrile butadiene styrene).

ABS is considered an all-round material among plastics. It is considered impact-resistant, break-proof and resistant to aqueous chemicals. However, tests have shown that a change in the surface appearance occurs with frequent contact with sweat. In contrast, the plastic plate segment made of the isosorbide-based polymer exhibits less of this surface appearance, which ultimately has less of an impact on the visual appearance of the remote control and thus the need for replacement of the remote control by the end user occurs to a lesser extent.

The plastic material may be executed as an isosorbide-based thermoplastic, in particular as a polycarbonate. Conventional polycarbonates are formed, for example, from diphenyl carbonate and aromatic diols. Isosorbide, on the other hand, is of plant origin and therefore leaves a smaller ecological footprint. Moreover, unlike many aromatics, isosorbide is not subject to any special hazard classification. R and S phrases for the special handling of isosorbide are not available, so that outgassing of monomers in case of degradation of the polymers e.g. by thermal heating, UV radiation, long-term weathering and the like is harmless.

The plastic material preferably has an elongation at break of more than 65%, in particular between 70-130%. This means that the material does not tend to break or crack under the influence of a mechanical shock, but deforms plastically. This ensures the tightness of the housing interior with the electronics.

Alternatively or additionally, the plastic material has a flexural modulus of more than 1700 MPa. Thus, the material reacts to punctual mechanical stress by a combination of plastic and elastic deformation.

The plastic housing advantageously has at least one upper shell and one lower shell. Particularly preferably, the plastic housing can be monolithic, with the upper shell and the lower shell being formed from the plastic material. A concrete realisation of a monolithic structure can be found in EP 3 393 753 B1, the structure of which is referred to in full in the context of the present invention.

The individual operating elements, preferably all operating elements, are part of the plastic plate segment in such a way that the plastic plate segment is monolithic. The tightness in combination with the improved elongation at break due to the use of the isosorbide-based polymer brings particular advantages in the event of a mechanical shock, e.g. by dropping the remote control, handling by small children and the like.

The control panel can have at least two different surface roughnesses, with one or preferably all of the control elements having a first surface roughness and the intermediate areas between the control elements having a second surface roughness. Accordingly, the plastic material used must be machinable and modifiable without negatively affecting other surface properties, in particular degeneratively, and with ensuring printability. In terms of printability, amorphous plastics are particularly suitable for forming the control panel. Thus, the use of an isosorbide-based amorphous thermoplastic is particularly preferred for forming the control panel and in particular also the plastic panel segment.

It is advantageous if the plastic material has a light transmission factor of more than 90%. High-gloss optics are an important purchase decision. The end-of-life cycle for remote controls is determined by the end customer and is based not only on the integrity of the material (break and scratch resistance), but also on the visual appearance of the remote control. A dull worn surface may also trigger disposal or replacement of the remote control. This characteristic applies to both transparent and generally infrared-transmissive material.

The plastic material may alternatively have a colouring for laser marking of the material.

The remote control may optionally have a transparent sensor window for emitting an optical sensor signal, wherein the sensor window may be made of the plastic material. An alternative data transmission may be via Bluetooth, in particular BLE. In this case, the sensor window is not absolutely necessary. However, both technologies can also be used complementary to each other.

Alternatively, the remote control may comprise a lower shell made of ABS material or a bisphenol-based polycarbonate material or the at least partially isosorbide-based polymer.

Furthermore, the transparent sensor window may be associated with the lower shell. A corresponding sensor window is often also called diode window. The sensor window may be made of ABS material or a bisphenol-based polycarbonate material or also of the at least partially isosorbide-based polymer.

In particular, the upper shell of the remote control may advantageously be made of the at least partially isosorbide-based polymer.

The control element(s) or the intermediate areas may thus advantageously be realised as a high-gloss appearance. Due to the insensitivity of the isosorbide-based polymer to grease and sweat, there is no dulling of the surface even in long-term use.

The plastic plate segment can have plug-in elements on the side opposite the control panel, which are very stable due to the high material stability and do not bend or break off when oblique forces are applied.

### BRIEF DESCRIPTION OF THE DRAWINGS

The above-described properties, features and advantages of this invention, as well as the manner in which they are achieved, will become clearer in connection with the following description of the embodiments, which are explained in more detail in connection with the drawing, in which:

FIG. 1 is a perspective view of the control panel of the remote control, and

FIG. 2 is the perspective rear view of the upper shell of the remote control; and

FIG. 3 is a schematic illustration of a measuring arrangement for determining the long-term effects of sweat on the plastic surfaces of an isosorbide-based material in comparison with ABS.

### LIST OF REFERENCE SIGNS

1 Remote control, 2 Plastic housing, 3 Upper shell, 4 Lower shell, 5 Keypads, 6 Button element, 8 Directional pad, 9 Button elements, 10 Button elements, 11 Button elements, 12 Button element, 13 Confirmation key, 14 Intermediate areas, 15 Plastic plate segment, 16 Plug-in elements

### DETAILED DESCRIPTION

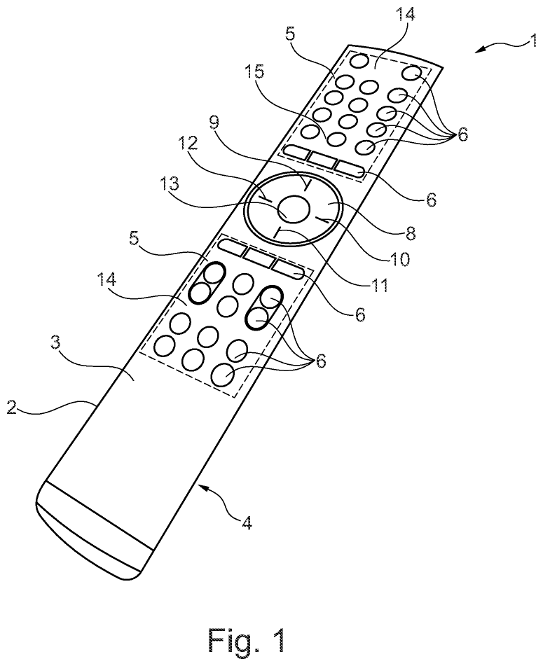

The figure is a purely schematic representation. Actual geometric relations may deviate from the figure. Reference is made to FIG. 1, which shows a remote control 1 to control an electronic device (not shown in further detail), such as a multimedia device, in a perspective view.

The remote control 1 comprises a plastic housing 2 consisting of a first housing part in the form of an upper shell 3 and a second housing part in the form of a lower shell 4, as well as two keypads 5 having a plurality of button elements 6. For the sake of clarity, not all of the button elements 6 in the keypad 5 are provided with reference signs in the drawings. A directional pad 8 is arranged between the two keypads 5, comprising a first button element 9, a second button element 10, a third button key element 11, and a fourth button element 12.

The four button elements 9 to 12 are arranged circumferentially and at a distance of 90° from one another around a confirmation key 13. The directional pad 8 having the four button elements 9 to 12 is designed as circular disc in this case. The remote control 1 also comprises feedback elements 14 in the form of small lights which can light up when a button is pressed on the remote control 1. The remote control 1 is used as an example to explain the operation of a multimedia device. To this end, a user uses the buttons 5 on the upper shell 3 of the remote control 1 to enter control commands into the remote control 1 in the form of data which is then transmitted to the electronic device to be controlled via a transmitter (not shown in further detail). Such a command can be entered, for example, as a direction command via the button elements 9 to 12, which command then controls the movement of a control element on the exemplary multimedia device in one of the four possible directions of movement.

The button elements 6 of the respective keypads, individual button elements 9-12 and also the directional pad 8 may protrude with respect to the intermediate areas 14 between the button elements, e.g. the button elements 6, or may alternatively be recessed with respect to the intermediate areas 14. The button elements 6 and the intermediate areas can merge into each other without gaps so that the upper shell forms a continuous, preferably monolithic, control surface. The finger position and thus the assignment on the button elements 6 can be sensed, for example capacitively. The button elements 6, 9-12, the keypads 5, the directional pad 8 and all other components on the control surface are arranged on a plastic plate segment 15, which is also continuous, preferably monolithic, and which is part of the upper shell 3. The average thickness of the plastic plate segment 15 is less than 3 mm, preferably less than 1.5 mm.

The plastic housing 2 can be manufactured, for example, by injection moulding. Individual or all button elements 6, 9-12 or also the directional pad 6 have a surface which has a different surface roughness compared to the adjacent intermediate areas 14. There is thus a first and a second surface roughness on the control surface of the upper shell 3, the second surface roughness being greater than the first surface roughness. In addition to an improved visual perception of the button elements and a more intuitive and thus faster operation, the differentiation of the surface roughness also enables a better operation in the dark. It is quite common and necessary to switch on a television in the dark and operate it in low light. The differentiated surface roughness enables the correct buttons to be felt, especially when the layout of the keypad is known.

A special feature of the upper shell 3 is its particularly high Charpy impact strength which, in the case of a notched specimen, is more than 6 kJ/m², in particular between 8.8 and 9.2 kJ/m² according to ISO 179-1eU in the current version as of September 2021 at 23° C., x mm. In the case of an unnotched specimen, the impact is without breakage due to the pronounced ductility or pliability of the material.

A further advantage is an elongation at break of the material of the upper shell 3 of more than 65%, in particular between 70-130%, according to ISO 527-1, -2 in the current version as of September 2021 at 50 mm/min.

This reduces the tendency to breakage in the event of mechanical shock, to an extent that frequently occurs in the household.

At the same time, the material of the upper shell 3 has a flexural modulus of more than 1700 MPa at 23° C., preferably between 1900-2300 MPa, according to ISO 527 in the current version as of September 2021.

This means that the material is not brittle, but in addition to its strength also has a corresponding degree of flexibility under the so-called three-point load.

Remote controls should also be visually appealing and easy to clean, especially with little use of solvents. The present plastic housing is advantageously resistant to ethanol, the most common organic solvent used in cleaning agents. An attractive appearance of the upper shell 3 is achieved by using a material with a light transmittance of more than 90%, according to ISO 13468-1,-2 at 3 mm.

Another preferred property is the resistance of the upper shell 3 to fatty acids. It is known that the human body has a fatty layer. In the frequent handling of remote controls, fatty acids have an influence on the material of the plastic housing. Fatty acids can be found in hand creams, but also in snacks such as crisps or the like.

In many common remote controls, a common polycarbonate is used as the hard plastic component, which becomes cloudy and loses its gloss under the influence of fatty acids. This is not the case with the material within the scope of the present invention. Conversely, matt surfaces can increasingly acquire a greasy sheen under the influence of fatty acids.

At least the button elements and/or the intermediate areas preferably have a high-gloss appearance. This can be realised, for example, by a highly polished surface within the injection mould or by a post-processing, e.g. by the step of precision glass moulding. A high-gloss appearance in the context of the present invention enables a light source, e.g. an LED light strip with distinguishable individual light sources, to be reflected on the surface in such a way that the light sources can also be distinguished in the mirror image of the remote control surface. This high-gloss appearance corresponds to the surface with the aforementioned first surface roughness. In contrast, the second surface roughness is designed in such a way that no reflection and possibly only a slight reflection of light emanates from the surfaces with this second surface roughness.

All these boundary conditions, which are of particular advantage for a remote control, can be achieved by using an isosorbide-based polymer.

Particularly preferably, an isosorbide-based thermoplastic, in particular polycarbonate, is used to manufacture the control panel of the upper shell 3. A further advantage is that a sensory detection of the finger position is also possible without the material of the control panel interfering too strongly with the sensor signal.

Particularly preferably, the entire upper shell 3 or the entire remote control is made of the aforementioned material.

The material can have a dye and thus be coloured in a colour, e.g. black, white or similar. It is advantageous if the remote control 1 has a transparent signal window in addition to the coloured area for transmitting an optical signal. This signal window can also be made of the aforementioned material. Due to its excellent transmission values and with a preferred refractive index between 1.49-1.53, a good transmission of an optical signal from or to a terminal device can take place.

A particular further advantage is the reduction of the ecological footprint, since isosorbides of sufficient quality for further processing into the plastic material of the plastic housing 2 can be obtained from biological, in particular vegetable, starting materials such as D-sorbitol. The D-sorbitol can be converted into isosorbide by dehydration and ultimately into polycarbonate by polymerisation (melt polymerisation).

Individual components, in particular the upper shell and the lower shell, can have plug-in elements, pins and/or plug-in sockets, for connection to each other and/or to electronic components, in particular to a printed circuit board. The pins preferably have a diameter of less than 2 mm. The same applies to the wall thickness of the sockets. Despite their small contact surface with the plastic plate 15, which is located on the side of the plastic plate segment 15 opposite the operating surface, these filigree plug-in elements 16 have an excellent resistance to buckling in the event of oblique forces acting on them.

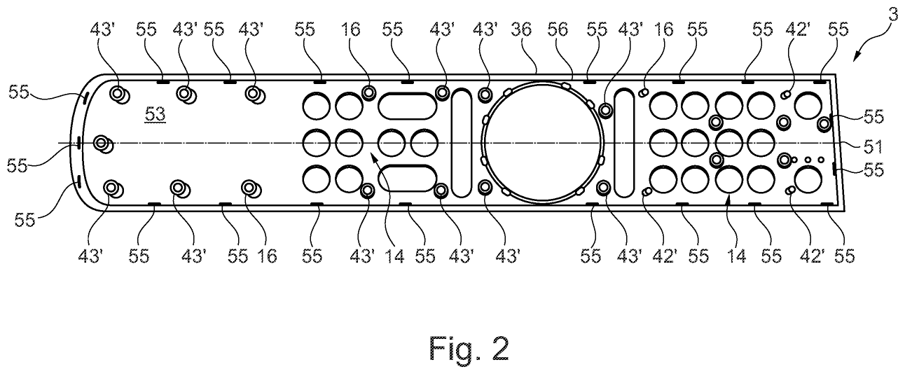

The plug-in elements 16 are shown as pins and/or sockets in FIG. 2.

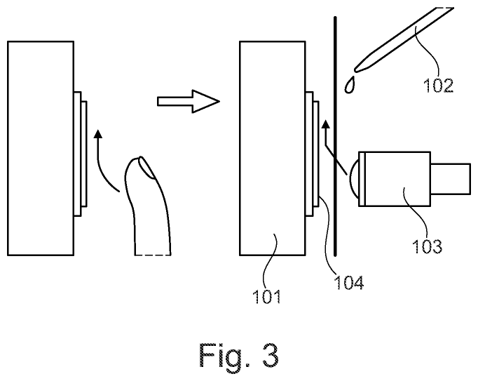

FIG. 3 discloses a measuring sequence for simulating hand abrasion. For this purpose, the Tribotouch 101 abrasion tester is used to simulate hand abrasion. The test is carried out in accordance with the European standard DIN EN 60068-2-70/IEC 68-2-70.

The aim is to expose the surface to be tested to a hand operation that is as realistic as possible. In addition to the mechanical load, the chemical environment is also simulated with artificial sweat 102.

A test stamp 103 defined in the standard will strike the surface of the test specimen 104 at an angle of 45° and travel a straight friction path of 1 . . . 4 mm. There must be a special friction fabric between the test stamp and the test specimen. In addition, the friction fabric is wetted with a test substance.

Friction path: 4 mm, test frequency: 2 Hz, test substance: artificial sweat, fabric feed every 10,000 cycles 10 mm, fluid feed every 1000 cycles 1 ml, severity 1 N, 5 N, and 10 N.

The load with 1 N takes a very long time, so it was decided to use 5 N and 10 N to make the comparison.

ABS material (acrylonitrile butadiene styrene) and polycarbonate made from isosorbide or polyisosorbide carbonate were tested.

The test was carried out by visually comparing the surfaces.

The polycarbonate material shows a significantly higher degree of stress-and thus a higher resilience-during simulated button presses with artificial sweat than the ABS used as standard.

Thus, it could be proven that the sweat resistance of the new material as an important factor for the housing material of a remote control is significantly higher than that of ABS. Artificial sweat in particular can be used for this purpose. The temperature is room temperature at 25° C. A lack of resistance is to be understood as a dissolving of the plastic and the associated loss of gloss of the plastic surface after removal of the sweat. ABS as the reference substance is dissolved to a greater extent and earlier than the isosorbide-based plastic.

1. A break-resistant electric remote control (1) for operating an electronic device comprising a plastic housing (2) with a plastic plate segment (15) with a control panel which has at least one control element, preferably button elements (6, 9-12) and/or at least one directional pad (8) for operating an electronic device,
wherein the plastic plate segment (15) is formed from a plastic material which has an Charpy impact strength, in particular in the case of a notched specimen, of more than 6 kJ/m², in particular of 9.0 kJ/m²+/−0.3 kJ/m²,
wherein the plastic material is formed as an at least partially isosorbide-based polymer.

2. The remote control according to claim 1, wherein the plastic plate segment (15) has a higher resistance to sweat than ABS (acrylonitrile butadiene styrene).

3. The remote control according to claim 2, wherein the plastic material is executed as an isosorbide-based thermoplastic, in particular as a polycarbonate.

4. The remote control according to claim 3, wherein the plastic material has an elongation at break of more than 65%, in particular between 70-130% and/or a flexural modulus of more than 1700 MPa.

5. The remote control according to claim 4, wherein the plastic housing (2) comprises at least an upper shell (3) and a lower shell (4), and is particularly formed monolithically therefrom, the upper shell (3) and the lower shell (4) being formed from the plastic material.

6. The remote control according to claim 5, wherein individual control elements, preferably all control elements, are part of the plastic plate segment (15) in such a way that the plastic plate segment (15) is monolithic.

7. The remote control according to claim 6, wherein the control panel has at least two different surface roughnesses, with one or preferably all of the control elements having a first surface roughness and the intermediate areas (14) between the control elements having a second surface roughness.

8. The remote control according to claim 7, wherein the plastic material has a colouring for laser-marking of the material.

9. The remote control according to claim 8, wherein the remote control comprises a lower shell (4) of ABS material or a bisphenol-based polycarbonate material or the at least partially isosorbide-based polymer.

10. The remote control according to claim 9, wherein the lower shell (4) has a transparent sensor window, in particular a diode window, for emitting an optical sensor signal, wherein the sensor window is made of ABS material or an bisphenol-based polycarbonate material or the at least partially isosorbide-based polymer.

11. The remote control according to claim 10, wherein the remote control comprises an upper shell (3), which is made from the at least partially isosorbide-based polymer.

12. The remote control according to claim 11, wherein at least the control element(s) or the intermediate areas (14) have a high-gloss appearance.

13. The remote control according to claim 12, wherein the plastic plate segment (15) has plug-in elements (16) on the side opposite the control panel.

14. The remote control according to claim 1, wherein the plastic material is executed as an isosorbide-based thermoplastic, in particular as a polycarbonate.

15. The remote control according to claim 1, wherein the plastic material has an elongation at break of more than 65%, in particular between 70-130% and/or a flexural modulus of more than 1700 MPa.

16. The remote control according to claim 1, wherein the plastic housing (2) comprises at least an upper shell (3) and a lower shell (4), and is particularly preferably formed monolithically therefrom, the upper shell (3) and the lower shell (4) being formed from the plastic material.

17. The remote control according to claim 1, wherein individual control elements, preferably all control elements, are part of the plastic plate segment (15) in such a way that the plastic plate segment (15) is monolithic.

18. The remote control according to claim 1, wherein the plastic material has a colouring for laser-marking of the material.

19. The remote control-according to claim 1, wherein the remote control comprises a lower shell (4) of ABS material or a bisphenol-based polycarbonate material or the at least partially isosorbide-based polymer.

20. The remote control according to claim 10, wherein the remote control comprises an upper shell (3), which is made from the at least partially isosorbide-based polymer.
